(19) United States
(12) Patent Application Publication
(10) Pub. No.: US 2013/0059425 A1
(43) Pub. Date: Mar. 7, 2013

(54) Imprinted Memory

(71) Applicant: Guobiao ZHANG, Corvallis, OR (US)

(72) Inventor: Guobiao ZHANG, Corvallis, OR (US)

(73) Assignee: CHENGDU HAICUN IP TECHNOLOGY LLC, ChengDu (CN)

(21) Appl. No.: 13/602,095

(22) Filed: Aug. 31, 2012

Related U.S. Application Data
(60) Provisional application No. 61/529,919, filed on Sep. 1, 2011.

(51) Int. Cl. H01L 21/02

(52) U.S. Cl. 438/381; 257/E21.003

(57) ABSTRACT

The rising mask cost would make mask-ROM economically un-viable below 90 nm. The present invention discloses an imprinted memory, more particularly a three-dimensional imprinted memory (3D-iP). It uses imprint-lithography (also referred to as nano-imprint lithography, or NIL) to record data. The data-template used by imprint-lithography is much less expensive than the data-mask used by photo-lithography.

### CROSS-REFERENCE TO RELATED APPLICATIONS

This application relates to a provisional application, “Three-Dimensional Printed Memory”, Application Ser. No. 61/529,919, filed Sep. 1, 2011.

### BACKGROUND

1. Technical Field of the Invention

The present invention relates to the field of integrated circuit, and more particularly to mask-programmed read-only memory (mask-ROM).

2. Prior Arts

Mask-ROM has been used to store contents. It comprises at least a data-coding layer. The pattern in the data-coding layer represents the digital data stored in the mask-ROM and it is referred to as a data-pattern. The mask-ROM in FIG. 1 is a cross-point mask-ROM. It comprises a plurality of top address lines (e.g. 2a-2d), bottom address lines (e.g. 1a-1d) and memory cells (e.g. 5aa-5dd). The width of the address lines is f. Here, f of interest is equal to or less than 100 nm. Its data-coding layer is a blocking dielectric 3b, which blocks the current flow between the top and bottom address lines. Absence or existence of a data-opening (e.g. a via) in the blocking dielectric 3b indicates the state of a memory cell. For example, absence of data-opening at the memory cell 5ab represents ‘0’, while existence of a data-opening at the memory cell 5aa represents ‘1’. This figure only shows the blocking dielectric 3b around the data openings (in cross-hatched pattern). To display the address lines and their relative placement with the data-openings, the blocking dielectric 3b are not shown in other areas. This figure also does not show the diode in the memory cell.

In the past, the data-pattern in the data-coding layer is transferred from a data-mask. Pattern-transfer is also referred to as “print”. Data-mask is the mask that carries the source image of the data to be printed. When the IC feature size gets smaller than the optical wavelength of the photo-lithography tools, various resolution-enhancement techniques (RET), such as optical proximity correction (OPC) and phase-shift mask, have to be used on the mask to compensate for the limitations of the photo-lithography. The introduction of these RET techniques greatly increases the data volume for the sub-100 nm mask, as well as its manufacturing complexity.

To make the matter worse, the data-pattern on the data-mask is different from general mask patterns, e.g. address-lines pattern, storage-pillar pattern, or storage-hole pattern. The address-lines pattern, storage-pillar pattern and storage-hole pattern exhibit strong micron-scale periodicity, i.e. they repeat periodically at certain intervals within micron range. Micron is an important dimension because it represents the diffraction range of the exposing light. These patterns are suitable for the RET techniques such as OPC and phase-shift mask. On the other hand, the data-pattern on the data-mask exhibits no micron-scale periodicity, i.e. it doesn't have periodicity at all within micron range. The data-pattern is not suitable for the RET techniques such as OPC and phase-shift mask. This significantly increases the manufacturing complexity of the data-mask. All these factors, added together, greatly drives up the data-mask cost after 90 nm. For example, a data-mask at 90 nm costs ˜$50 k (1 k=1,000); while a data-mask at 22 nm costs ˜$250 k. The rising mask cost would make mask-ROM economically un-viable below 90 nm.

### Objects and Advantages

It is a principle object of the present invention to provide a method to lower the data-recording cost.

It is a further object of the present invention to provide a method to lower the data-mask cost.

In accordance with these and other objects of the present invention, an imprinted memory, more particularly a three-dimensional imprinted memory (3D-iP), is disclosed.

### SUMMARY OF THE INVENTION

The present invention discloses an imprinted memory, more particularly a three-dimensional imprinted memory (3D-iP). It uses imprint-lithography to record data. Imprint-lithography is also referred to as nano-imprint lithography (NIL). It creates patterns by mechanical deformation of imprint resist and subsequent processes. A key benefit of using imprint-lithography for data-recording is the low-cost of its data-template. Here, the data-template is the template (also referred to as stamp, master or mold) that is used to transfer data-pattern to the data-coding layer. Because the pattern on the data-template is a 1:1 copy of the pattern in the data-coding layer, i.e. there is no optical distortion, the data-template doses not need OPC and therefore, the data volume for a data-template is much less than that for a data-mask. In addition, because imprint-lithography does not suffer from optical diffraction, the data-template does not need to use phase-shift technique. Hence, complex mask manufacturing process can be avoided. More importantly, imprint-lithography makes it possible to print the nanometer-scale patterns (from 1 nm to 100 nm, inclusive) which do not have micron-scale periodicity. Overall, because it is much easier to manufacture the data-template than the data-mask, the data-template is much less expensive that the data-mask. As a result, the imprinted memory has a low data-recording cost.

### BRIEF DESCRIPTION OF THE DRAWINGS

FIG. 1 illustrates a data-pattern in a mask-ROM.

FIGS. 2A-2C discloses processing steps of a preferred imprint-lithography.

FIGS. 3A-3B are top views of the data-patterns on two preferred data-templates.

FIG. 4 illustrates a preferred three-dimensional imprinted memory (3D-iP).

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

To lower the data-recording cost, the present invention discloses an imprinted memory, more particularly a three-dimensional imprinted memory (3D-iP). As to its final physical structures, the imprinted memory is same as the mask-ROM. Both use the data-pattern in the data-coding layer to store data. They differ in their data-recording method: the imprinted memory uses imprint-lithography, while the mask-ROM uses photo-lithography. These methods have different data-recording cost: the data-template used by imprint-lithography is much less expensive than the data-mask used by photo-lithography.

Imprint-lithography creates patterns by mechanical deformation of imprint resist and subsequent processes (referring to Chou et al. Imprint-lithography with 25-naonmeter resolution, Science, Vol. 272, No. 5258, pp. 85-87). Imprint-lithography includes thermoplastic nano-imprint lithography, photo nano-imprint lithography, electro-chemical nano-imprint lithography, laser-assisted direct imprint lithography. Imprint-lithography may use a full-wafer imprint scheme, or a step-and-repeat imprint scheme.

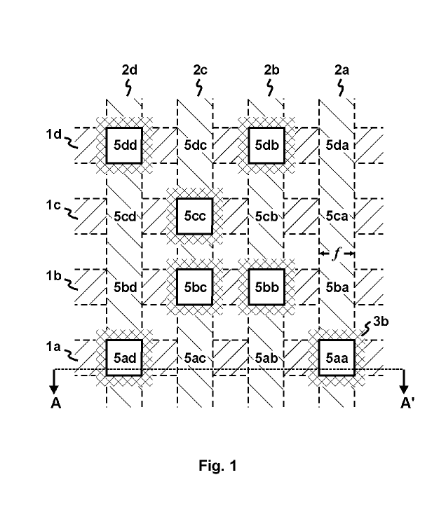

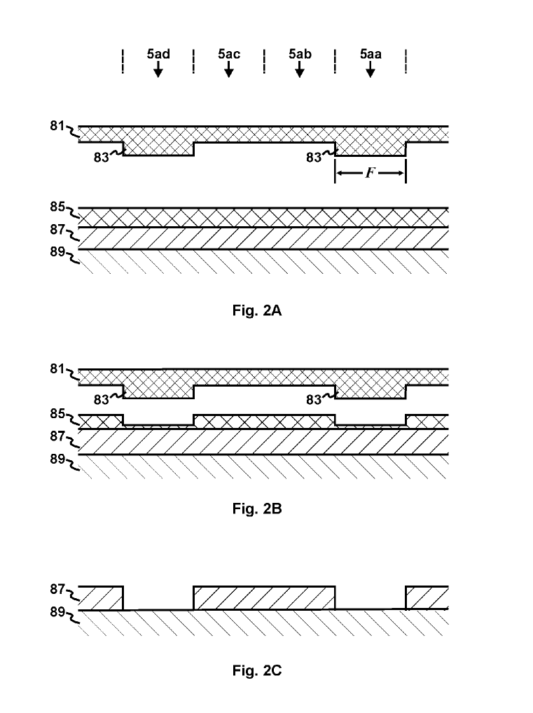

FIGS. 2A-2C discloses processing steps of a preferred imprint-lithography. These figures are the cross-sectional views along the cut-line AA′ of FIG. 1. These steps are used to record data for the memory of FIG. 1. This preferred imprint-lithography is thermoplastic nano-imprint lithography. Its detailed processing steps are as follows. First of all, the data-coding layer 87 is formed on a bottom layer 89 (e.g. an address line). Then a thin layer of imprint resist (e.g. thermoplastic polymer) 85 is spin coated on the data-coding layer 87 (FIG. 2A). A template 81 is brought into contact with the imprint resist 85 and they are pressed together under certain pressure. When heated up above the glass transition temperature of the polymer, the pattern on the template 81 is pressed into the softened polymer film. After being cooled down, the template 81 is separated from the wafer (FIG. 2B). Finally, an etching process is carried out to transfer the pattern in the resist 85 to the data-coding layer 87 (FIG. 2C).

The template 81 has a predefined topological pattern. It comprises a plurality of mesas 83, which protrudes out of a surface of the template. The dimension of these mesas ranges from 1 nm to 100 nm, inclusive. The absence or existence of a mesa at a location on the template determines on the state of the memory cell corresponding to this location. For example, if the location for a memory cell (e.g. 5ab) has no mesa, then this memory cell has no data-opening (FIG. 1) and is in state “0”; on the other hand, if the location for a memory cell (e.g. 5aa) has a mesa 83, then this memory cell has a data-opening (FIG. 1) and is in state “1”. Note that, after imprint-lithography, the shape of the imprint resist 85 is inverse to the shape of the template 81.

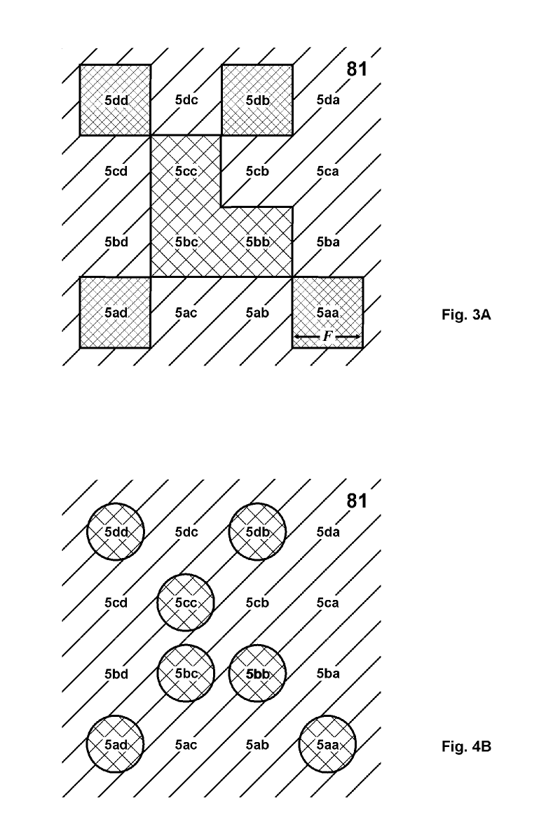

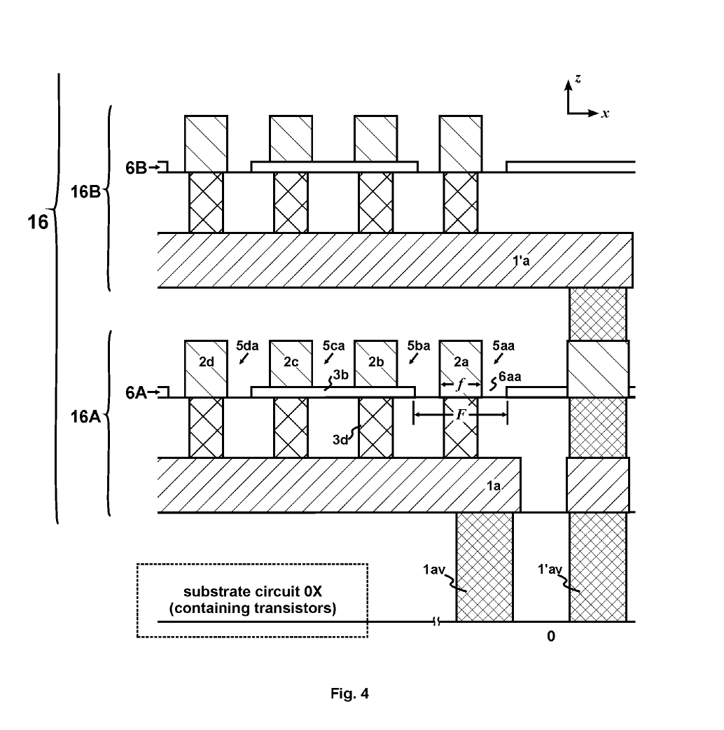

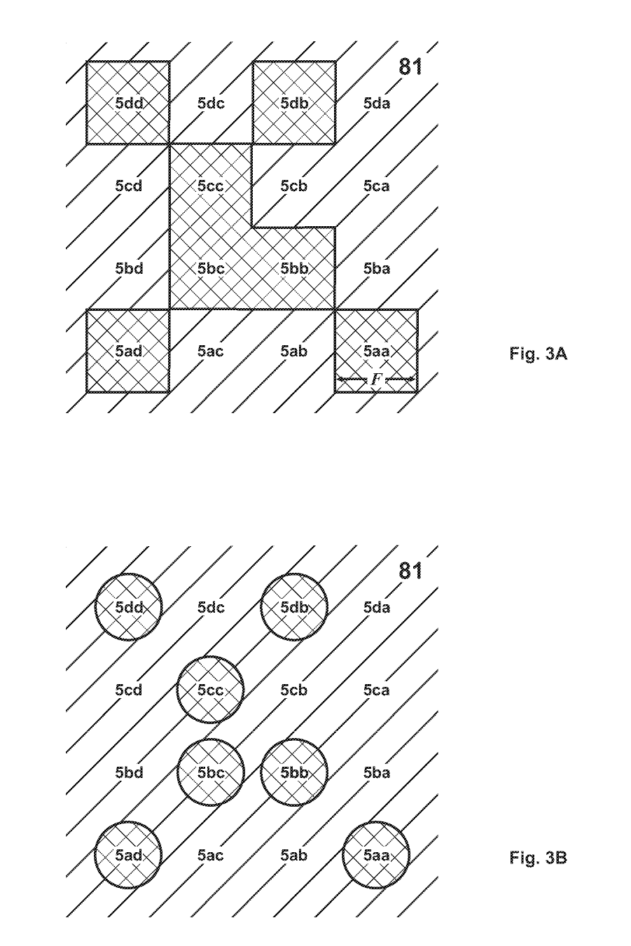

FIG. 3A illustrates the data-pattern on a preferred data-template 81. The minimum feature size f of its mesa (e.g. the one at the location 5aa) could be larger than, preferably twice as much as, the minimum feature size f of the imprinted memory, e.g. the minimum half-pitch (or, the width) of its address lines (referring to U.S. Pat. No. 6,903,427). Accordingly, the data-template 81 is also referred to as x f-template (with x>1, preferably ˜2). This can significantly lower the data-template cost. For example, a 45 nm imprinted memory can use a 90 nm data-template. In this preferred embodiment, the mesas 83 have a rectangular shape.

FIG. 3B illustrates the data-pattern on another preferred data-template 81. Its mesa (e.g. the one at the location 5aa) has a circular cylinder shape. These mesas could also have a cone shape or a pyramidal shape. These shapes can be easily formed by electron beams that directly write data onto the data-template 81.

A key benefit of using imprint-lithography for data-recording is the low-cost of its data-template. Because the pattern on the data-template is a 1:1 copy of the pattern in the data-coding layer, i.e. there is no optical distortion, the data-template doses not need OPC. For each bit in the imprinted memory, the data-template needs only a single bit to define the absence or existence of a mesa. In comparison, for each bit in a mask-ROM, the data-mask needs several bits to define the shape of the mask opening. Therefore, the data volume for a data-template is much less than that for a data-mask. In addition, because imprint-lithography does not suffer from optical diffraction, its data-template does not need to use phase-shift technique. Hence, complex mask manufacturing process can be avoided. More importantly, imprint-lithography makes it possible to print the nanometer-scale patterns (from 1 nm to 100 nm, inclusive) which do not have micron-scale periodicity. Overall, because it is much easier to manufacture the data-template than the data-mask, the data-template is much less expensive that the data-mask. As a result, the imprinted memory has a low data-recording cost.

Imprint-lithography can be used in three-dimensional printed memory (3D-P) (referring to the co-pending application “Three-Dimensional Printed Memory”). Accordingly, the present invention discloses a three-dimensional imprinted memory (3D-iP). It uses imprint-lithography to record data into its memory levels. FIG. 4 illustrates a preferred 3D-iP. It has the same physical structures as the traditional 3D-MPROM, but different data-recording means: the 3D-iP uses imprint-lithography, while the 3D-MPROM uses photo-lithography. The 3D-iP is a diode-based cross-point memory. It comprises a semiconductor substrate 0 and a 3-D stack 16 stacked above. The 3-D stack 16 comprises M (M2) vertically stacked memory levels (e.g. 16A, 16B). Each memory level (e.g. 16A) comprises a plurality of upper address lines (e.g. 2a), lower address lines (e.g. 1a) and memory cells (e.g. 5aa). Each memory cell comprises a diode and stores n (n≧1) bits. Each memory level further comprises at least a data-recording layer, such as blocking dielectric, resistive layer (referring to U.S. patent application Ser. No. 12/785,621) or extra-dopant layer (referring to U.S. Pat. No. 7,821,080). Data are recorded into the data-coding layer of the memory levels using imprint-lithography. Memory levels (e.g. 16A, 16B) are coupled to the substrate 0 through contact vias (e.g. 1av, 1av′). The substrate circuit OX in the substrate 0 comprises a peripheral circuit for the 3-D stack 16.

While illustrative embodiments have been shown and described, it would be apparent to those skilled in the art that may more modifications than that have been mentioned above are possible without departing from the inventive concepts set forth therein. The invention, therefore, is not to be limited except in the spirit of the appended claims.

What is claimed is:

1. A method of manufacturing an imprinted memory, comprising the steps of:
1) forming a data-coding layer;
2) transferring a data-pattern from a data-template to said data-coding layer using imprint-lithography;
3) forming a plurality of address lines coupled to said data-pattern in said-coding layer;
wherein said data-pattern represents data stored in said imprinted memory; said data-template comprises nanometer-scale patterns, but does not have micron-scale periodicity.

2. The method according to claim 1, wherein said imprinted memory is a cross-point memory.

3. The method according to claim 1, wherein said imprint-lithography is nano-imprint lithography.

4. The method according to claim 1, wherein said imprint-lithography is thermoplastic nano-imprint lithography.

5. The method according to claim 1, wherein said imprint-lithography is photo nano-imprint lithography.

6. The method according to claim 1, wherein said imprint-lithography is electro-chemical nano-imprint lithography.

7. The method according to claim 1, wherein said imprint-lithography is laser-assisted direct imprint-lithography.

8. The method according to claim 1, wherein said imprint-lithography uses full-wafer imprint.

9. The method according to claim 1, wherein said imprint-lithography uses step-and-repeat imprint.

10. The method according to claim 1, wherein said imprint-lithography uses a data-template.

11. The method according to claim 10, wherein said data-template comprises a plurality of mesas.

12. The method according to claim 11, wherein the dimension of said mesas ranges from 1 nm to 100 nm inclusive.

13. The method according to claim 11, wherein the minimum feature size of said mesas is larger than the minimum half-pitch of said address lines.

14. The method according to claim 11, wherein said mesas have a circular cylinder shape.

15. The method according to claim 11, wherein said mesas have a cone shape.

16. The method according to claim 11, wherein said mesas have a pyramidal shape.

17. The method according to claim 1, wherein said imprinted memory is a three-dimensional imprinted memory (3D-iP) comprising a plurality of vertically stacked memory levels, wherein each of said memory levels comprises at least a data-coding layer and data are recorded into said data-coding layer using imprint-lithography.

18. The method according to claim 2, wherein said data-coding layer is a blocking dielectric.

19. The method according to claim 2, wherein said data-coding layer is a resistive layer.

20. The method according to claim 2, wherein said data-coding layer is an extra-dopant layer.
